(19) United States
(12) Patent Application Publication
(10) Pub. No.: US 2025/0142726 A1
(43) Pub. Date: May 1, 2025

(54) FILM-TYPE CIRCUIT AND METHOD OF CONNECTING PRINTED CIRCUIT BOARDS VIA FILM-TYPE CIRCUIT

(71) Applicant: DENSO WAVE INCORPORATED, Chita-gun (JP)

(72) Inventor: Natsuki SUGIMOTO, Chita-gun (JP)

(73) Assignee: DENSO WAVE INCORPORATED, Chita-gun (JP)

(21) Appl. No.: 18/928,945

(22) Filed: Oct. 28, 2024

(30) Foreign Application Priority Data
Oct. 26, 2023 (JP) 2023-184004

(51) Int. Cl. H05K 1/14; H05K 1/02; H05K 1/11; H05K 3/34

(52) U.S. Cl. CPC H05K 1/148; H05K 1/028; H05K 1/118; H05K 3/3494; H05K 2201/1034; H05K 2203/0195; H05K 2203/167

(57) ABSTRACT

A film-type circuit is used to accurately align the film-type circuit between two printed circuit boards to be electrically connected via the film-type circuit. This film-type circuit includes a wiring part having connection parts at both ends in a predetermined direction of the film-type circuit. An insulation part is formed to cover the wiring area. The insulation layer is formed to expose a partial connection side of each connection part, the connection side being connected to a corresponding one of the two printed circuit boards. The film-type circuit is curved in its length to have a warpage in a side view. At least two through-holes are formed at designated positions in the film-type circuit, without overlapping between the insulation layer and the wiring patterns, in a center portion in the predetermined direction, and are separate from each other in a direction orthogonal to the predetermined direction.

### CROSS-REFERENCE TO RELATED APPLICATION

This application is based on and claims the benefit of priority from earlier Japanese Patent Application No. 2023-184004 filed Oct. 26, 2023, the description of which is incorporated herein by reference.

### BACKGROUND

### Technical Field

The present disclosure relates to a film-type circuit such as an FPC (Flexible Printed Circuit) and an FFC (Flexible Flat Cable) and connection of the film-type circuit to an PCB (Printed Circuit Board), and in particular, to how the film-type circuit is connected between two PCBs for connection of the two PCBs.

### Background Art

A film-type circuit is known as an FPC and an FFC, which have a thin flat and flexible electronic circuit including electronic wirings. For example, such a film-type circuit is known by a patent reference 1 disclosed by JP-A 2012-49297.

This patent reference 1 exemplifies an FFC functioning as a film-type circuit, in which multiple conductors arranged in parallel in the width direction of the conductors are bonded and covered with an insulating film in the thickness direction of the conductors to form a single wiring device. In addition, exposed portions where the conductors are partly exposed from the insulating film are formed at both ends of the conductor in the longitudinal direction. Each of the exposed portions on both end sides is bonded to a corresponding electrode provided on each printed circuit board (PCB), thus mutually connecting the two printed circuit boards via the film-type circuit.

### [Patent Reference]

[Patent reference 1] JP-A 2012-49297

### Technical Problem

In the connection structure shown in Patent Document 1, the electrodes (wiring patterns) of the two printed circuit boards are connected by an FFC (film-type circuit).

In such a structure, the FFC is frequently entirely warped or curved to delineate a gentle arc when viewed from a side thereof even before assembly with the printed circuit boards. Hence, if the FFC is warped, it becomes difficult to mate the foregoing positioning conductors with the foregoing holes on both the printed circuit boards, i.e., it becomes difficult to accurately position the FFC with respect to both the printed circuit boards. In particular, when the printed circuit boards and the film-type circuit are automatically positioned by a positioning device, such difficulties are unacceptable.

### SUMMARY

It is thus desired to accurately align a film-type circuit to both printed circuit boards when the film-type circuit connecting the wiring patterns of the two printed circuit boards is warped.

As an exemplary embodiment, there is provided a film-type circuit to be connected with two printed circuit boards, comprising:
a wiring part formed of an electrically conductive material, formed to be a layer-shaped wiring patterns for conductive connection of the two printed circuit boards via the film-type circuit, and formed to have connection parts at both ends of the wiring part in a predetermined direction of the film-type circuit, and
an insulation layer formed of an electrical insulating material in a layered form and formed to cover the wiring part, the insulation layer still being formed to expose a partial connection side of each of the connection parts, the connection side being connected to a corresponding one of the two printed circuit boards.

In this configuration, the film-type circuit is warped such that the partial connection side of each of the connection parts is directed inward in a warped curve and the connection parts positioned to be closer in the predetermined direction compared to a state where the film-type circuit is flat. Moreover, the film-type circuit has at least two through-holes formed at designated positions in the film-type circuit, the designated positions being set to have no overlapping between the insulation layer and the wiring patterns, to be located in a center portion in the predetermined direction, and to be separated from each other in a direction orthogonal to the predetermined direction.

It is preferred that the film-type circuit comprises a plurality of reinforcing terminals made of an electrically conductive material, each formed to have a width larger than a width of the respective wiring patterns, and positioned restrictively at end portions of the film-type circuit in both a direction orthogonal to the predetermined direction and the predetermined direction, wherein the designated positions of the through-holes are set in end areas of the film-type circuit in the direction orthogonal to the predetermined direction, each of the designated positions in the respective end areas being located between two of the reinforcing terminals opposed to each other on the film-type circuit in the predetermined direction.

It is also preferred that the film-type circuit the through-holes are two in number. The through-holes may be equal in sizes thereof to each other or different in sizes thereof from each other.

Another exemplary embodiment of the present disclosure relates to a method of mutually connecting the two printed circuit boards via a film-type circuit, comprising preparing, fixing, bringing and guiding steps. Of these steps, the preparation step prepares a film-type circuit, comprising:
a wiring part formed of an electrically conductive material, formed to be a layer-shaped wiring patterns for conductive connection of the two printed circuit boards via the film-type circuit, and formed to have connection parts at both ends of the wiring part in a predetermined direction of the film-type circuit, and
an insulation layer formed of an electrical insulating material in a layered form and formed to cover the wiring part, the insulation layer still being formed to expose a partial connection side of each of the connection parts, the connection side being connected to a corresponding one of the two printed circuit boards,
wherein the film-type circuit is warped such that the partial connection side of each of the connection parts is directed inward in a warped curve and the connection parts positioned to be closer in the predetermined direction compared to a state where the film-type circuit is flat, and
the film-type circuit has at least two through-holes formed at designated positions in the film-type circuit, the designated positions being set to have no overlapping between the insulation layer and the wiring patterns, to be located in a center portion in the predetermined direction, and to be separated from each other in a direction orthogonal to the predetermined direction.

In the fixing step, the two printed circuit boards fixed onto a positioning jig provided with at least two positioning pins. In a joining step, the film-type circuit and the positioning pin are brought close together such that the positioning pins are inserted into the through-holes, respectively, from the connection sides of the connection parts of the film-type circuit. Further, the film-type circuit is guided on and along the warpage such that the positioning pins are closer to the through-holes located at the center in the predetermined direction.

When mounting a film-type circuit on printed circuit substrates according to a conventional technique, positioning accuracy of the film-type circuit to the substrates may be reduced due to a warpage of the film-type circuit, of which whole portion is curved in its length, i.e., in its predetermined direction. If it is desired to use the component with no such warpage, yield and part costs for producing such a component are confronted with difficulties.

In contrast, the foregoing exemplified embodiments basically feature that, when the film-type circuit is loaded between two printed circuit boards for mutual electrical connection, the film-type circuit is given a curved shape in its length, i.e., a warpage in advance in a side view. How the warpage (or the curved surface in a side view) is generated positionally and in size can be controlled by adjustably adding through-holes to the film-type circuit. Hene, by using an inexpensive film-type circuit and positively utilizing the warpage (curve) generated on such an inexpensive film-type circuit, it is possible to improve yield and reduce costs during manufacturing.

Other various advantageous operations and effects derived from the foregoing exemplary embodiments will be described later together with explanations of the accompanying drawings.

### BRIEF DESCRIPTION OF DRAWINGS

In the accompanying drawings:

FIG. 1 is a partial side view showing connection parts connected between wirings of a printed circuit board and wirings of an FFC;

FIG. 2 is a plan view showing two printed circuit boards positioned on a positioning jig;

FIG. 3 is a plan view showing a positioning mode between the two printed circuit boards and the FFC;

FIG. 4 is a partial side view showing a mode in which the two printed circuit boards and the FFC are positioned by positioning pins:

FIG. 5 shows a plan view and a side view both showing the FFC;

FIGS. 6A to 6D are illustrations explaining a connection method performed between the FFC and two printed circuit boards, in which the FFC is guided by a warpage of the FFC;

FIG. 7 is a plan view showing a mode in which blank portions of a reinforcing terminal and circular portions of a connection terminal are positioned for mutual connection;

FIGS. 8A and 8B are enlarged plan views each explaining alignment of the blank portion of the reinforcing terminal and the circular portion of the connection terminal;

FIG. 9 shows the plan view and the side view both showing the FFC, in which a heading tool presses and heats both connection parts of electrical wirings of the printed circuit board and reinforcing terminals of the FFC for bonding to the printed circuit board;

FIG. 10 is an illustration explaining a part of the connection method in which the heating tool is applied to ends of the FFC to mutually connect the wirings of the printed circuit board and the connection parts of the wrings of the FFC;

FIG. 11 is a pictorial side view showing how the printed circuit boards are connected via the FFC and folded back in order to be installed into a PLC;

FIG. 12 shows a plan view and a side view both showing a modified FFC in which the position of a through-hole is changed; and

FIG. 13 shows a plan view and a side view both showing another modified FFC in which the position of a through-hole is shifted from a virtual center line in a short direction of the FFC.

### DESCRIPTION OF THE PREFERRED EMBODIMENTS

With reference to the accompanying drawings, an embodiment of a film-type circuit will now be described.

The film-type circuit can be provided as a film-type circuit such as an FPC (Flexible Printed Circuit) and an FFC (Flexible Flat Cable). In the present embodiment, the film-type (shaped) circuit will be explained as an FFC provided with a plurality of liner wiring patterns (composing a wiring area) in a designated direction thereof. The FFC is shaped into a thin flexible rectangular flat plate, but as being flexible, the FFC can easily be warped in a substantially controllable manner of its curvature, as will be described later, such that the FFC itself is bent to an arc over its length in a side view. In the present embodiment, the warpage of the FFC plays a key role in positioning the FFC between the two printed circuit boards for connecting such two printed circuit boards in series via the FFC.

In the present embodiment, the FFC is formed into a rectangular shape in a plan view thereof, but instead of such rectangular shape, a trapezoidal shape is also applicable to the FFC. In the FFC according to the present disclosure, an electric circuit is provided as a plurality of electrical wiring patterns (arranged in a wiring area) which run in a layer laminated between insulation layers, whereby both ends of the wiring patterns are connected to electric connection terminals of each of the two printed circuit boards for electrically serial connection of the two printed circuit boards installed into, for example, a programmable logic controller (PLC). The film-type circuit can also be realized by an FPC.

In the present embodiment, how the FFC is positioned between the printed circuit boards, then the FFC is moved to fix the positions of the three elements: the first printed circuit board, the FFC, and the second printed circuit board, and finally fixing the positions will be explained.

The present embodiment will now be detailed.

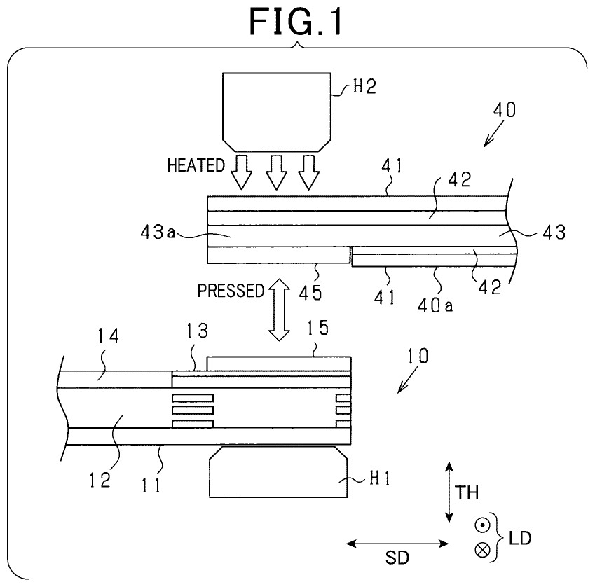

As shown in FIG. 1, there is provided a printed circuit board 10 having a substrate 11, an internal pattern 12, wiring patterns 13, an insulation layer 14, and a solder layer 15. Of these layered elements, the substrate 11 is formed in the shape of a rectangular plate, for example, using epoxy resin. The internal pattern 12 is composed of a circuit pattern formed using an electrically conductive material and the insulation layer 14 formed using an insulating material, which are alternately laminated. The internal pattern 12 is covered by the insulation layer 14. The multiple wiring layers 13 are formed on the insulation layer 14 (exposed from the insulation layer 14) using an electrically conductive material (e.g. copper). The solder layer 15 is provided on the top (outside) of the respective wiring patterns 13. Alternatively, the solder layer 15 may be omitted, and the multiple wiring patterns 13 may be exposed on the surface of the printed circuit board 10.

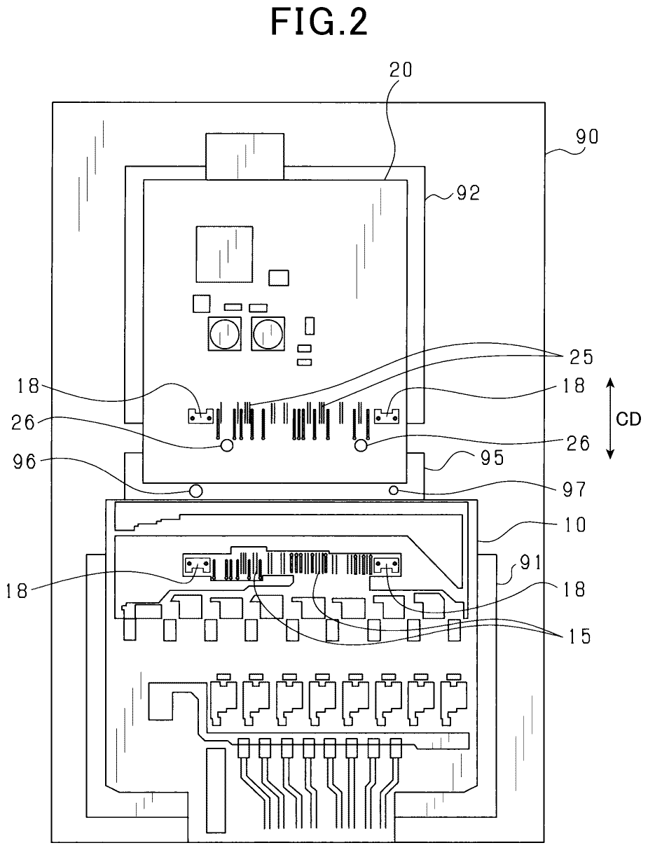

In addition, the printed circuit board 20 (see FIG. 2) is also provided with a substrate 11, an internal pattern 12, wiring patterns 13, an insulation layer 14, a solder layer 15, which are formed in the same way as that of the printed circuit board 10.

The FFC 40 (film-type circuit) includes wiring patterns 43, an adhesive layer 42, an insulation layer 41, and a solder layer 45.

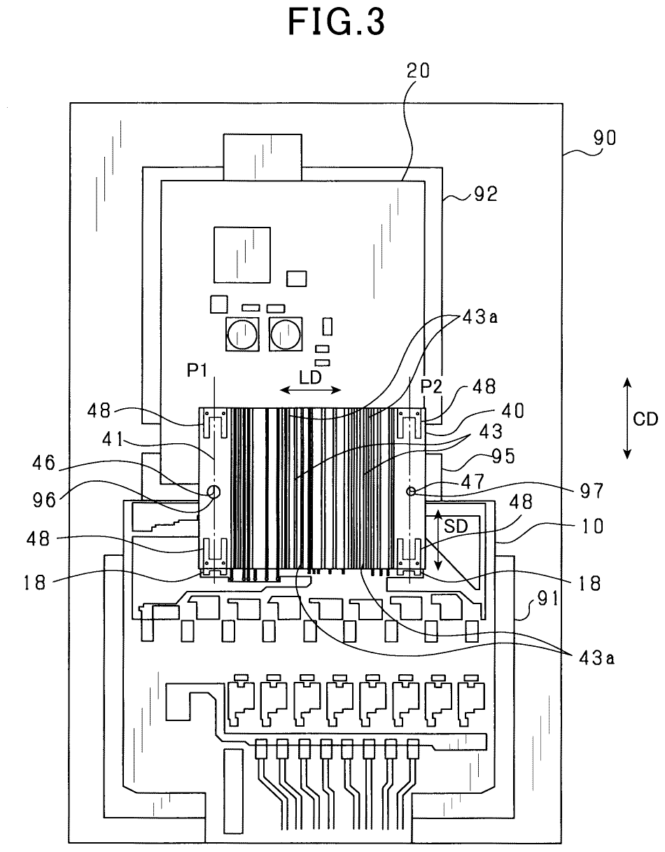

First, when the FFC 40 maintains a flat plate shape, the shape of the FFC 40 can be used to define the orientation necessary to explain the structure of the FFC and the electric interconnection of the two printed circuit boards 10 and 20. As shown in FIG. 3, the FFC 40, as a whole, is formed in a flat rectangular, or more specifically, rectangular film shape. Therefore, the FFC 40 has long and short sides of its rectangular shape, and the direction along the short side can be defined as a short direction (also referred to as a predetermined or designated direction) SD, while the direction along the longer side orthogonal to the short direction SD can be defined as a longitudinal direction LD. Furthermore, the direction along the thickness of the FFC 40 can be defined as a thickness direction TH. When the FFC 40 is flat in shape, this thickness direction TH, the short direction SD (i.e., the predetermined direction) and the longitudinal direction LD described above form three mutually orthogonal axial directions.

The plurality of electrical wiring patterns 43 are made of an electrically conductive material (e.g., copper) of constant thickness and are linear, but when viewed from the direction along a plane along both the directions SD and LD, the wiring patterns 43 are formed in a layer (see FIG. 1). When viewed in the thickness direction TH, the plurality of wiring patterns 43 are arranged in the wiring area PA, pattern by pattern, parallel along the short direction SD to form a plane shape as a whole. The insulation layer 41 is adhered to each of the two sides of the plurality of wiring patterns 43 in the thickness direction TH via an adhesive layer 42, except for some structures at the ends of the plurality of wiring patterns 43 in the short direction SD.

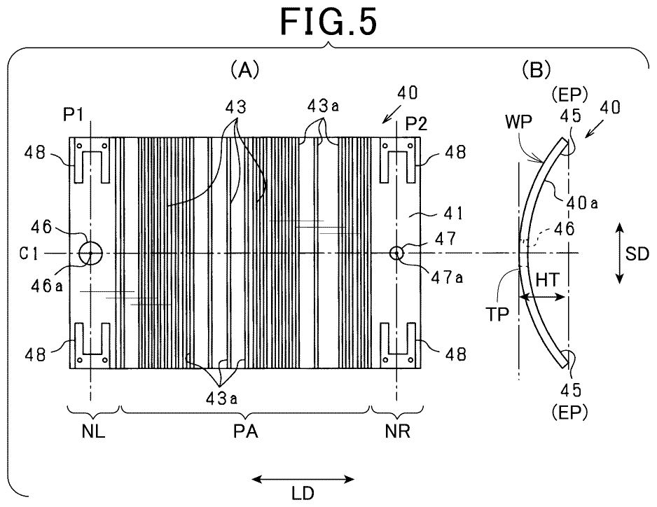

If explained more specifically, an area left between mutually adjacent two wiring patterns, for example, a narrow-angle area SA in FIG. 5 can be referred to as a non-wired area, even though such non-wired areas are present in the wiring area PA.

In detail, the plurality of wiring patterns 43 have predetermined portions at each end in the short direction SD thereof formed as connection parts 43a (see FIGS. 1 and 3). In other words, the connection part 43a is formed at each end of both ends of the straight wiring patterns 43 in the short direction SD. Since one side of this connection part 43a in the thickness direction TH is used for electrical connection with the printed circuit board 10 (20), the one side is covered (filled) by the insulation layer 41, except for this electrical connection side. In other words, the insulation layer 41 is provided to expose the electrical connection side of the connection part 43a. As shown in FIG. 1, the solder layer 45 is provided on the exposed portion (electrical connection side) of the connection part 43a. Although only the one connection part 43a is depicted in FIG. 1, a connection part 43a structured in the same way is also formed at the other end of the plurality of wiring patterns 43 in the short direction SD (see FIG. 3). The insulation layer 41 is made of a flexible and insulating material, such as polyimide, and is formed in film form. The adhesive layer 42 is an insulating adhesive, such as epoxy adhesive. The connection part 43a may be provided slightly inward from each of the ends of the straight wiring patterns 43 in the short direction SD. The plurality of wiring patterns 43 compose a wiring part in the connection structure.

The electric connection between the printed circuit board 10 and the FFC 40 is generally performed as follows. The position corresponding to the solder layer 15 of the plurality of wiring patterns 13 of the printed circuit board 10 is preheated by the heating tool H1 of a preheater from the opposite side of the solder layer 15 (see FIG. 1). Then, the solder layer 15 of each wiring pattern 13 of the printed circuit board 10 is aligned with the solder layer 45 of the connection part 43a of each wiring pattern 43 of the FFC 40. In this aligned state, the heating tool H2 of the heater is used to thermo-compress the FFC 40 onto the printed circuit board 10 (see FIG. 1). As a result, the solder layer 15 of each wiring pattern 13 of the printed circuit board 10 and the solder layer 45 of the connection part 43a of each wiring pattern 43 of the FFC 40 are melted and connected to each other.

Then, in a similar manner as the foregoing, the solder layer 15 of each wiring pattern 13 of the printed circuit board 20 and the solder layer 45 of the connection part 43a of each wiring pattern 43 of the FFC 40 are aligned with each other. In this aligned state, the FFC 40 is thermo-compressed to printed circuit board 20 by the heating tool H2 of the heater. As a result, the solder layer 15 of each wiring pattern 13 of the printed circuit board 20 and the solder layer 45 of the connection part 43a of each wiring pattern 43 of the FFC 40 are melted and connected with each other.

FIG. 2 shows a plan view of the two printed circuit boards 10 and 20 and a positioning jig 90. The positioning jig 90 has a first fixing member 91, a second fixing member 92, a pin support member 95, positioning pins 96 and 97.

The first fixing member 91 is formed in a shape corresponding to the printed circuit board 10 and is able to position and fix the printed circuit board 10. For example, the printed circuit board 10 has a plurality of positioning through-holes (not shown). The first fixing member 91 is provided with insertion pins (not shown) each of which can be inserted into a corresponding one of the positioning through-holes of the printed circuit board 10. The insertion pins of the first fixing member 91 are inserted into the multiple positioning through-holes of the printed circuit board 10. This enables the printed circuit board 10 to position and fix to the first fixing member 91. The second fixing member 92 is formed in the same structure as that of the first fixing member 91, and is able to position and fix the printed circuit board 20. The printed circuit board 10 is fixed to the first fixing member 91, while the printed circuit board 20 is fixed to the second fixing member 92. In these fixed states, an edge with the foregoing solder layer 15 on the printed circuit board 10 and an edge with the foregoing solder layer 15 on the printed circuit board 20 are opposed to each other.

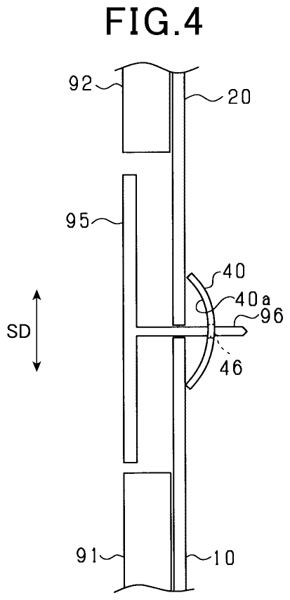

As shown in FIG. 2, the pin support member 95 is located between the first fixing member 91 and the second fixing member 92 on the positioning jig 90 in a connecting direction CD corresponding to the short direction SD of the FFC 40. The pin support member 95 supports the positioning pins 96 and 97 which are mounted thereon to rise upward. That is, as shown in the partial side view in FIG. 4, the positioning pins 96 and 97 (only the positioning pin 96 is shown in FIG. 4) extend vertically upward from the pin support member 95. The positioning pins 96 and 97 are cylindrical in shape and tapered at their tips, respectively. Of these pins 96 and 97, the diameter of the positioning pin 96 is larger than the diameter of the positioning pin 97. The positioning pins 96 and 97 are positioned between the first fixing member 91 and the second fixing member 92 in the connecting direction CD. The printed circuit board 10 is fixed to the first fixing member 91 and the printed circuit board 20 is fixed to the second fixing member 92. In these fixed states, as shown in FIG. 2, the positioning pins 96 and 97 are positioned between the printed circuit board 10 and the printed circuit board 20 in the connecting direction CD.

In the printed circuit board 20, suction holes 26 are formed at a position on the side of printed circuit board 10 rather than the solder layer 15 is, in the connecting direction CD. A vacuum pump (not shown) is connected to the suction holes 26 via air intake tubes. When the vacuum pump is driven, negative pressure is supplied to the suction holes 26 via the air intake tubes.

FIG. 3 is a plan view showing the alignment of the two printed circuit boards 10 and 20 and the FFC 40. As shown in FIG. 3, a film-shaped insulation layer 41 is transparent, so that the wiring patterns 43 and reinforcing terminals 48 are visible via the insulation layer 41. FIG. 4 is a partial side view showing the alignment of the two printed circuit boards 10 and 20 and the FFC 40 realized by the positioning pins 96 and 97.

As shown in FIG. 5, through holes 46 and 47 are formed through the FFC 40 at positions in the specified-width non-wired end areas NL and NR which are set both ends in the longitudinal direction LD, where the positions of the through holes 46 and 47 are matched positionally to the positioning pins 96 and 97 of the positioning zig 90, respectively, when being assembled. The through holes 46, 47 are formed in shapes and sizes corresponding to the positioning pins 96 and 97, respectively. Specifically, the diameters of the through holes 46 and 47 are the same as or slightly larger than the outer diameters of the positioning pins 96 and 97, respectively. In the FFC 40, the positioning pins 96 and 97 are inserted into the through holes 46 and 47 from the surface 40a on the connection side (which faces the solder layer 45) of the foregoing connection part 43a, respectively. As a result, the position of the FFC 40 with respect to the positioning pins 96 and 97, that is, the position of the position of FFC 40 with respect to the printed circuit boards 10 and 20 fixed to the fixing parts 91 and 92, respectively, is fixed.

FIG. 5, a part (A) therein, is a plan view of the FFC 40 and FIG. 5, a part (B) therein, is a side view of the FFC 40. In FIG. 5 (A), the film-shaped insulation layer 41 is shown, through which the wiring patterns 43 and reinforcing terminals 48 are visible.

The respective wiring patterns 43 extend linearly in the short direction SD (i.e., the predetermined direction) of both the insulation layer 41 and the FFC 40. The plurality of wiring patterns 43 are aligned in the longitudinal direction LD (orthogonal to the predetermined direction) of both the insulation layer 41 and FFC 40. The through-holes 46 and 47 are formed at the portions of the insulation layer 41 which do not overlap the wiring patterns 43, specifically at both end portions of the insulation layer 41 in the longitudinal direction LD. The through-holes 46, 47 are circularly formed. The diameter of the through-hole 46 is larger than that of the through-hole 47. In other words, as one of preferred examples, the through-holes 46 and 47 are different in size from each other. The respective centers 46a and 47a of the through-holes 46 and 47 are located on the center line C1 of the insulation layer 41 and FFC 40 in the short direction SD. In other words, at least two through-holes are formed at the parts of the insulation layer 41 that does not overlap with the wiring patterns 43. These through-holes pass through the center of the insulation layer 41 in the short direction SD and are separated from each other in the longitudinal direction LD of the insulation layer 41.

The FFC 40 has reinforcing terminals 48 formed of an electrically conductive material (e.g., copper). The reinforcing terminals 48 are formed with a width wider than the width of each of the wiring patterns 43. The reinforcing terminals 48 are located at the four corners (i.e., at both ends of the respective non-wired end areas NL and NR in the longitudinal direction LD and at both ends in the short direction SR) of the surface 40a of the FFC 40, which exists on the connection side (the side where the solder layer 45 is exposed) of the connection part 43a (refer to FIGS. 1 and 4). The respective reinforcing terminals 48 are also provided with a solder layer 45. The through-holes 46 and 47 are formed at both ends of the insulation layer 41 in the longitudinal direction LD and between the reinforcing terminals 48 in the short direction SD. In other words, the one through-hole 46 and the two reinforcing terminals 48 on the left side in FIG. 4 are located at the same position P1, with no significant design displacement therebetween, in the longitudinal direction of the insulation layer 41, while the other through-hole 47 and the remaining two reinforcing terminals 48 on the right side in FIG. 4 are located at the same position P2, with no significant design displacement therebetween, in the longitudinal direction of the insulation layer 41,

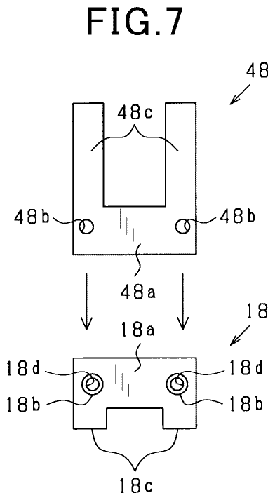

As shown in FIG. 7, the respective reinforcing terminals 48 are groove-shaped (i.e., U-shaped) in a plan view thereof. Each of the reinforcing terminals 48 has a bottom 48a and two feet 48c. The width of both the bottom 48a and the feet 48c is wider than the widths of the respective wiring patterns 43. Blank portions 48b are formed at both ends of the bottom portion 48a in the longitudinal direction. The blank portions 48b (which function as a first positioning mark) are circularly formed with no electrically conductive material filled therein.

On the printed circuit boards 10 and 20, connection terminals 18 (i.e., terminal 18 to be connected) are formed by an electrically conductive material (e.g., copper) at positions which positionally corresponds to the reinforcing terminals 48 of the FFC 40, respectively (see FIG. 2). As shown in FIG. 7, the connection terminal 18 is formed in a groove shape (U-shape) in a plan view thereof. The connection terminal 18 has also a bottom portion 18a and two leg portions 18c. The total width of both the bottom portion 18a and the leg portions 18c is wider than the width of the respective wiring patterns 13 in the longitudinal direction LD. Blank portions 18b are formed at both ends of the longitudinal direction of bottom portion 18a. The blank portions 18b are circular in shape due to the absence of electrically conductive material. The diameter of each of the blank portions 18b of the connection terminal 18 is larger than the diameter of each of the blank portions 48b of the reinforcing terminals 48. Inside the respective blank portions 18b, a circular portion 18d (serving as a second positioning mark) is formed by an electrically conductive material. The center of each of the blank portions 18b is positionally set to be consistent with the center of each circular portion 18d. The diameter of each of the circular portions 18d is smaller than the diameter of each of the blank portions 48b. The distance between the centers of the two blank portions 48b of each of the reinforcing terminals 48 is equal to the distance between the centers of the two circular portions 18d of each of the connection terminals 18.

As an alternative example, the connection terminals 18 may also be provided with a solder layer 15.

The cross-sectional structure of the FFC 40 is as shown in FIG. 1, in which a warpage WP occurs in the FFC 40 due to the asymmetry in the layered configurations of the FFC 40 in the thickness direction TH. Specifically, the FFC 40 is warped so that the connection side (the surface 40a) of the connection part 43a is inward and the solder layer 45 (the connection parts 43a) at both ends EP in the short direction becomes closer to each other. If the through-holes 46 and 47 were not formed through the FFC 40, the warpage of the FFC 40 would not be constantly the same. For example, the FFC 40 warps so that the two ends in the longitudinal direction LD approach each other, or the reinforcing terminals 48 positioned diagonally approach to each other. The larger the FFC 40, the greater the effect of warpage, i.e., how much the FFC 40 warps.

By way of example, the rectangular sizes of the FFC 40 are 36 mm and 43 mm in the short and longitudinal directions SL and DL, and the height HT from a line passing both ends EP to the top TP ranges from a few millimeters to a few centimeters, depending on how deeply the warpage WP is made.

On the other hand, the inventor has noticed that the FFC 40 tends to occur a warpage starting from the through-holes in the insulation layer 41 because the strength of the part where the through-holes are formed is lower than that of other parts. In other words, by adjusting the positions of through-holes formed though the insulation layer 41, the warpage of the FFC 40 (i.e., substantially corresponding to the curvature of the FFC 40) can be controlled with high reproducibility even if the FFC 40 becomes larger. In the present embodiment, the through holes 46 and 47, which are separated from each other in the longitudinal direction LD of the insulation layer 41, are formed to pass through the center of the insulation layer 41 in the short direction SD. This allows the FFC 40 to be warped so that the area including the center in the short direction SD becomes a vertex caused in the FFC 40.

Furthermore, the through-holes 46 and 47 are formed at both ends of the insulation layer 41 in the longitudinal direction LD. As a result, the starting points for the warping of FFC 40 can be set at both ends of the insulation layer 41 in the longitudinal direction LD. This makes it easier to warp the entire FFC 40 so that the range including the center in the short direction SD becomes the apex. In addition, the respective centers 46a and 47a of the through-holes 46 and 47 are positioned in the center of the insulation layer 41 in the short direction SD. This makes it easier to warp the entire FFC 40 so that the center in the short direction SD becomes the apex.

The serial connection of the printed circuit boards 10 and 20 and the FFC 40 is carried out as follows. The following process may be carried out automatically by the equipment or manually by the operator.

First, as shown in FIG. 2, the printed circuit board 10 is fixed to the first fixing member 91 of the positioning jig 90, while the printed circuit board 20 is fixed to the second fixing member 92. To be specific, the two printed circuit boards 10 and 20 are fixed to the positioning jig 90 equipped with the two positioning pins 96 and 97.

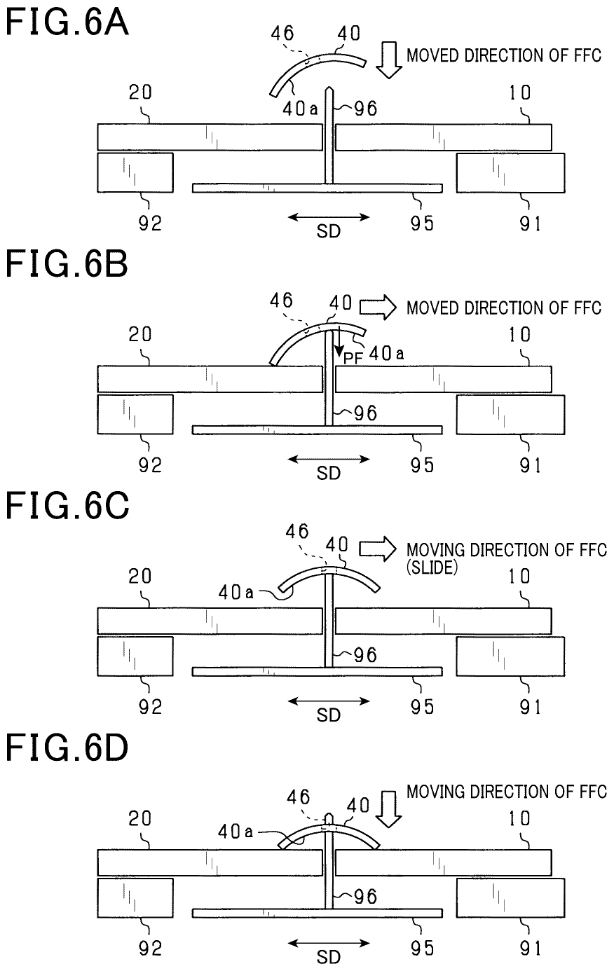

Then, as shown in FIG. 6A, the FFC 40 is moved closer to the positioning pins 96 and 97 (only the positioning pin 96 is illustrated in the figure) such that the positioning pins 96 and 97 are inserted into the through holes 46 and 47 (only the through hole 46 is illustrated in the figure) from the surface 40a on the connection side of the connection part 43a of the FFC 40. In the present embodiment, a default position (i.e., an initial position or a standard starting position) of the FFC 40 with respect to the positions of the printed circuit boards 10 and 20 is set previously, and the FFC 40 is moved, manually or machine-based atomically, closer to the positioning pins 96 and 97 from the default position. Although the default position is set such that the position of the FFC 40 is aligned with respect to the printed circuit boards 10 and 20, the FFC 40 positioned at the default position may vary about its positions. Alternatively, when moving the FFC 40 from the default position to the positioning pins 96 and 97, the positions of the through holes 46 and 47 of the FFC 40 may shift from the positions of the positioning pins 96 and 97. On one hand, since the FFC 40 is not warped in the longitudinal direction LD, the positions of the positioning pins 96 and 97 and the positions of the through holes 46 and 47 of the FFC 40 are unlikely to be displaced in the longitudinal direction LD.

In this connection work, as shown in FIG. 6B, when the FFC 40 is brought even closer to the positioning pins 96, 97, the tips of the positioning pins 96, 97 touch the surface 40a of the connection side provided by the connection part 43a of the FFC 40. Then, with the tips of the positioning pins 96 and 97 and the through-holes 46 and 47 slightly misaligned, a pressing force is exerted on the tips of the positioning pins 96 and 97 to press the surface 40a of the FFC 40. This pressing force pressing the surface 40a of the FFC 40 against the tips of the positioning pins 96 and 97 may be exerted by an arm of a device (such as an industrial robot) gripping the FFC 40, or by a worker manually, or by gravity.

As described, the FFC 40 is warped such that the central part thereof has a smoothly bent curved apex, i.e., a smoothly curved warp in the short direction SD (left and right directions in FIGS. 6A-6D). Thus, a pressing force PF is exerted to press the surface 40a of the FFC 40 against the tips of the positioning pins 96 and 97. As shown in FIG. 6C, this causes the FFC40 to slide against the positioning pins 96 and 97 such that the positioning pins 96 and 97 approach the central part of the FFC 40 in the short direction SD. Practically, the FFC 40 is automatically guided by the warpage in a manner that the positioning pins 96 and 97 approach the central part of the FFC 40 in the short direction SD.

When the ends of the through-holes 46 and 47 reach the tips of the positioning pins 96 and 97, the positioning pins 96 and 97 are inserted, so as to be pulled in, into the through-holes 46 and 47, respectively, as shown in FIG. 6D. In other words, the position of the FFC 40 is positioned, i.e., aligned with the positioning pins 96 and 97, and thus, with the printed circuit board 10 and 20. In this inserted state, the position of the FFC 40 is fixed at the two through-holes 46 and 47 of the FFC 40 with respect to the printed circuit boards 10 and 20. Therefore, the rotation of the FFC 40 with respect to the printed circuit board 10 and 20 is regulated, i.e., prevented.

Then, an area which covers the solder layer 15 of the multiple wiring patterns 13 of the printed circuit board 10 is preheated by the heating tool H1 of the preheater, from the opposite side of the solder layer 15.

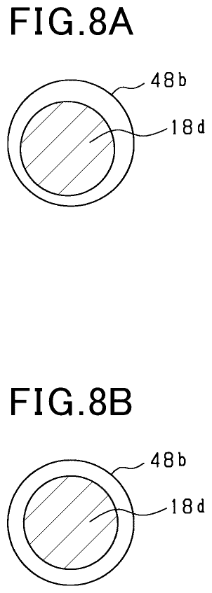

Then, with the positioning pins 96 and 97 inserted into the through-holes 46 and 47, a total of four blank portions 48b of the two reinforcing terminals 48 of the FFC 40 facing the printed circuit board 10 are aligned with the four circular portions 18d of the two connection terminals 18 facing the printed circuit board 10, respectively, as shown in FIG. 7. Specifically, if the center of the circular portion 18d and the center of the blank portions 48b are misaligned at each aligned position as shown in FIG. 8A, the center of the circular portion 18d and the center of the blank portions 48b are aligned as pictorially shown in FIG. 8B. More specifically, the position of the blank portions 48b relative to the circular portion 18d is adjusted such that the area of the blank portions 48b left around the circular portion 18d is maximized.

In the same way, a total of four blank portions 48b of the two reinforcing terminals 48 of the FFC 40 facing the printed circuit board 20 are aligned with the four circular portions 18d of the two connection terminals 18 facing the printed circuit board 20, respectively, in the same manner as that shown in FIG. 7.

The process of aligning the center of each of the circular portions 18d with the center of corresponding each of the blank portions 48b may be performed automatically based on image recognition with use of imaging devices such as an optical camera, or it may be performed manually by the operator using a magnifying glass or the like. In such an alignment process, the FFC 40 may be moved, the printed circuit boards 10 and 20 (i.e., the fixed portions 91, 92) may be moved, or both the FFC 40 and the printed circuit boards 10, 20 may be moved in combination.

The negative pressure from the suction holes 26 is then used to enable the printed circuit board 20 to suction the FFC 40 thereto. Specifically, a vacuum pump is driven to supply negative pressure to the adsorption holes 26 through the intake tubes.

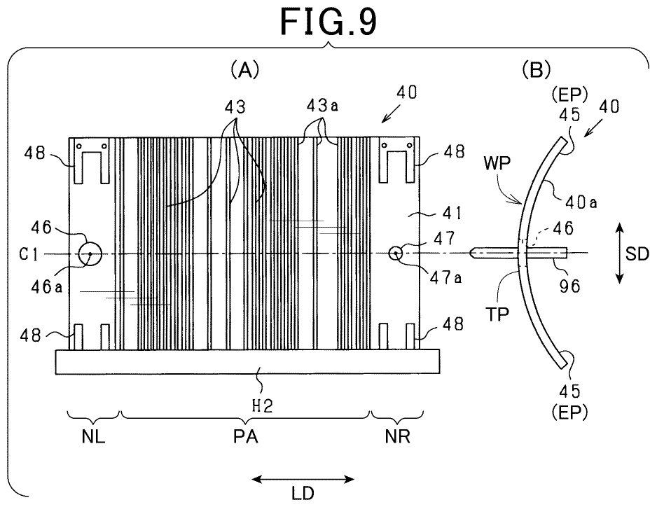

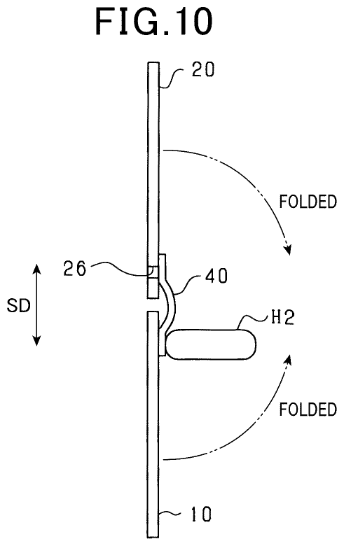

As shown in FIG. 9, the heating tool H2 of the heater is formed longer than the longitudinal length of the FFC 40 in the longitudinal direction LD. Then, the heating tool H2 presses the edge of the FFC 40, which faces the printed circuit board 10, downward (in the direction toward the printed circuit board 10) over its entire length. Specifically, the heating tool H2 presses and heats an overall area including the connection parts 43a (i.e., the solder layer 45) and the reinforcing terminals 48 at both ends of the FFC 40 together in the longitudinal direction LD. As a result, the wiring patterns 13 of the printed circuit board 10 and the solder layer 15 of the connection terminal 18 are thermo-compressed (refer to FIG. 10). This melts the solder layer 45 of both the connection part 43a and the reinforcing terminals 48, and the solder layer 15 of both the wiring patterns 13 and the connection terminals 18, resulting in mutual connection. In other words, the heating tool H2 connects the wiring patterns 13 of the printed circuit board 10 to the connection side of the connection part 43a of the FFC40. At the same time, the connection terminals 18 of the printed circuit board 10 is connected to the reinforcing terminals 48 of the FFC 40. In this process, heat from the heating tool H2 is transferred in the short direction of the insulation layer 41 via the wiring patterns 43, but reluctant to the through-holes 46 and 47 formed in the non-wired end areas NL and NR that does not overlap with the wiring patterns 43.

Then, the heating tool H2 of the heater is raised (away from the FFC 40) and moved to the edge of the FFC 40 which faces the printed circuit board 20. Then, in the same manner as the foregoing, the edge of the FFC 40, which faces the printed circuit board 20, is pressed downward (in the direction to the printed circuit board 20) over its entire length. Specifically, the heating tool H2 presses and heats the connection part 43a (i.e., the solder layer 45) and the reinforcing terminals 48 at both ends of the FFC 40 collectively, resulting in thermo-compression being performed between the wiring patterns 13 of the printed circuit board 20 and the solder layer 15 of the connection terminals 18. This thermo-compression melts not only the solder layer 45 of connection part 43a and the reinforcing terminals 48 but also the solder layer 15 of the wiring patterns 13 and the connection terminal 18, thus being connected to each other.

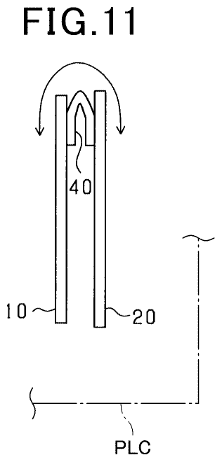

As shown in FIG. 11, the printed circuit board 10, FFC 40, and printed circuit board 20 are mounted on the PLC with FFC 40 folded back. In this case, the predetermined direction also corresponds to the direction along the short direction SR of the FFC40 as shown by an arrow in FIG. 11, whereby the wiring patterns 43 of the FFC 40 are also bent and extended along the bent direction SR.

The foregoing embodiment provides the following various advantageous operations and effects.

The through-holes 46, 47 are formed through the FFC 40, i.e., specifically in the insulation layer 41 of the FFC 40 that does not overlap with the plurality of electrical wiring patterns 43 (composing the electrical wiring part), and are spaced apart from each other. Therefore, the two printed circuit boards 10 and 20 are fixed to the positioning jig 90 equipped with the positioning pins 96 and 97. In this fixed state, the positioning pins 96, 97 are inserted into the through holes 46, 47 of the insulation layer 41 of the FFC 40, respectively. This allows the FFC 40 to be aligned with both printed circuit boards 10 and 20. Furthermore, by inserting the positioning pins 96 and 97 into the two through holes 46 and 47 which are separated from each other, the rotation of the FFC 40 with respect to both the printed circuit boards 10 and 20 can be restricted. Thus, the connection parts 43a near both ends of the plurality of wiring patterns 43 can be precisely aligned with the wiring patterns 13 of both the printed circuit boards 10 and 20, respectively.

The FFC 40 itself is curved in its length, i.e., warped such that the connection sides of the connection part 43a (the side where the solder layer 45 is provided) are directed inward (i.e., come closer to each other in the short direction SR). The inventor has studied that the parts where the through-holes 46 and 47 are formed in the insulation layer 41 of the FFC 40 are weaker in strength than the other parts, so that the FFC 40 tends to warp easily starting from the through-holes 46 and 47. In other words, by adjusting the positions of the through-holes 46 and 47 in the insulation layer 41, the warpage of the FFC 40 can be controlled with high reproducibility. The two-through holes 46 and 47, which are separated from each other, are passed by the virtual center line in the short direction SR. This geometry allows the FFC 40 to be warped so that the central part in the short direction SR becomes a vertex from which the entire part are gradually rounded. Thus, a force which pushes the FFC 40 and positioning pins 96 and 97 acts in a state where there is some misalignment between the positioning pins 96 and 97 and the through holes 46 and 47 of the insulation layer 41. When this pushing force is applied, the FFC 40 is automatically guided by the warpage so that the positioning pins 96 and 97 approach the central part of the FFC 40 in the short direction SR. Therefore, even when the printed circuit boards 10 and 20 and the FFC 40 are automatically aligned by an assembly device, it is easier for the device to accurately align the FFC40 to both the printed circuit boards 10 and 20.

The positioning of the FFC 40 is based on its warpage, i.e., the flat cable of which whole portion is curved in its length in the short direction SR, so it is possible to assume that the FFC 40 is warped before the positioning. Therefore, an inexpensive FFC 40 with a deeper curve (i.e., warpage), i.e., its curvature radius is larger, which has been difficult to adopt as the FFC in the past, can be used in the present embodiment. In addition, the FFC 40 can also be made larger in size.

The through-holes 46 and 47 are formed at both ends of the longitudinal direction LD (which is orthogonal to the predetermined short direction SD) in the insulation layer 41. According to this configuration, the starting points for producing the warped (curved) FFC 40 can be set at both ends of the FFC 40 in the longitudinal direction LD. This makes it easier to warp or curve the entire FFC40 so that the central part including the center becomes the apex in the short direction SR.

The through-holes 46, 47 are circularly formed. In addition, the centers 46a and 47a of the through holes 46 and 47 are located on the virtually drawn center line C1 passing the insulation layer 41 in the short direction SR. According to such a configuration, it is easier to warp or curve the entire FFC 40 so that the center in the short direction SR becomes the apex.

The reinforcing terminals 48 are made of an electrically conductive material with a width wider than the width of the electrical wiring patterns 43, and are located at both ends in the longitudinal direction LD and both ends in the short direction SD on the FFC 40. Hence, the connection terminals 18 are formed at positions corresponding to the reinforcing terminals 48 of the FFC 40 on each of the printed circuit boards 10 and 20. The connection terminals 18 of each of the printed circuit boards 10 and 20 are thus connected to the reinforcing terminals 48 of the FFC 40. This connection construction can improve the connection strength between the printed circuit board 10 and 20 and the FFC 40.

The through holes 46 are 47 are formed at both end portions, i.e, the non-wired areas NL and NR of the insulation layer 41 (i.e. the FFC 40) in the longitudinal direction LD and between the two reinforcing terminals 48 in the short direction SR. Thus, the through holes 46 and 47 can be formed using the end portions that do not overlap with the reinforcing terminals 48 in both end portions of the insulation layer 41 in the longitudinal direction LD. Therefore, it is possible to suppress the lengthening of the longitudinal direction of the FFC 40, on and through which the reinforcing terminals 48 and through holes 46, 47 are formed. The through-holes 46, 47 formed at both end portions of the insulation layer 41 in the longitudinal direction LD may be different in size from each other. According to this size configuration, when connecting the FFC 40 to each of the two printed circuit boards 10 and 20, it is possible to reduce or avoid errors such as misrecognizing the front and rear surfaces of the FFC 40 or the back and front directions of the FFC 40.

Meanwhile, the positioning jig 90 has the first fixing member 91 that fixes the printed circuit board 10 and the second fixing member 92 that fixes the printed circuit board 20. Each of the positioning pins 96 and 97 is positioned between the first fixing member 91 and the second fixing member 92. To this configuration, there can be applied a method of connecting the printed circuit board 10 and 20 and the FFC 40. The method includes the process of fixing the printed circuit board 10 to the first fixing member 91 and fixing the printed circuit board 20 to the second fixing member 92. According to this process, the FFC 40 can be easily aligned with the printed circuit board 10 fixed to the first fixing member 91 and the printed circuit board 20 fixed to the second fixing member 92.

In the present embodiment, the positioning pins 96 and 97 are first inserted into the through holes 46, 47, and then the center of the blank portions 48b and the center of the circular portion 18d are aligned. Hence, the FFC40 is aligned to both the printed circuit boards 10 and 20 by the positioning pins 96 and 97. The position of the FFC 40 with respect to the printed circuit boards 10 and 20 can then be fine-tuned using the blank portions 48b and the circular portion 18d. The blank portions 48b are included in the reinforcing terminals 48 of the FFC 40. Thus, when the reinforcing terminals 48 are formed on the FFC 40, the blank portions 48b can also be formed together. In addition, the circular portion 18d is included in the connection terminal 18 of each of the printed circuit boards 10 and 20. Thus, when forming the respective connection terminals 18 on the printed circuit boards 10 and 20, the circular portion 18d can be formed together. In addition, the connection terminals 18 of the printed circuit boards 10 and 20 are connected to the reinforcing terminals 48 of the FFC 40. This can enhance a connection strength provided between the printed circuit board 10 and 20 and the FFC 40.

The connection part 43a and the reinforcing terminals 48 of the FFC 40 are pressed together and heated by heater tool H2. As a result, the wiring patterns 13 of the printed circuit boards 10 and 20 are connected to the connection sides of the connection parts 43a of the FFC 40, and at the same time, the connection terminals 18 of the printed circuit boards 10 and 20 are connected to the reinforcing terminals 48 of the FFC 40. Thus, the connection between the printed circuit boards 10 and 20 and the FFC 40 can be executed efficiently. Furthe, the through holes 46 and 47 are formed through the insulation layer 41 in its portions that do not overlap with the plurality of wiring patterns 43. Therefore, even if the heat from the heater tool H2 is transferred along the plurality of wiring patterns 43, the through holes 46 and 47 can be suppressed from being deformed by the heat. Therefore, when the wiring patterns 13 of the printed circuit board 10 and the connection sides of connection parts 43a of the FFC40 are connected by the heater tool H2, it is possible to prevent the FFC40 from positionally shifting with respect to the printed circuit board 20 on the opposite side of the heater tool H2.

The foregoing embodiment may be implemented with the following modifications. The same elements or structures as those described in the foregoing embodiment will be referred to by the same reference numerals or symbols.

The blank portions 48b (i.e., the first positioning marks) and circular portions 18d (i.e., the second positioning marks) can be omitted in the configurations described in the first embodiment.

The heating tool H2 may be separated into a heating tool that presses all the connection parts 43a (i.e., the solder layer 45) of the FFC 40 and a heating tool that presses the respective reinforcing terminals 48. The timing of pressing all the connection part 43a (i.e., the solder layer 45) and the timing of pressing the respective reinforcing terminals 48 may be different from each other.

In the foregoing embodiment and modifications, the reinforcing terminals 48 and connection terminals 18 can be omitted.

In the foregoing embodiment and modifications, instead of employing the solder layers 15 and 45, anisotropic conductive films (ACF: Anisotropic Conductive Film) can be employed to establish mutual connection between the printed circuit boards 10 and 20 and the FFC 40.

In the foregoing embodiment and modifications, the through-holes 46 and 47 may be shaped to be the same size. The through-holes 46 and 47 are not limited to a circular shape, but may be oval, square, rectangular, triangular, or other polygonal shapes. Even in these various other shapes, the cross-sectional lateral shape of the positioning pins 96 and 97 should be matched to the shape of the through holes 46 and 47.

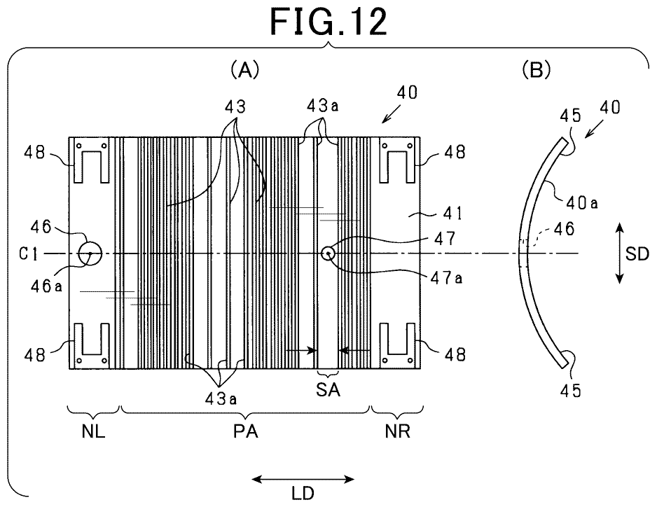

Another modification is provided in FIG. 12, which can also be in the foregoing embodiments and various modifications. That is, the through-hole 47 may be formed at a portion of the insulation layer 41 which is other than the non-wired end area NR in the longitudinal direction LD. In this modification, the center 47a of the through-hole 47 is located on the center line C1 (in the central portion in the short direction SR), but even in this case, the FFC 40 is formed to easily be warped by forming the through-holes 46 and 47, whereby the rotation of the FFC 40 can be regulated by the positioning pins 96 and 97 inserted into the through-holes 46 and 47, respectively.

Alternatively, the through-hole 47 may additionally be formed at a non-wired end area NR of the insulation layer 41 in the longitudinal direction LD, resulting in that the through-hole 46 and the two through-holes 47 may be formed through the insulation layer 41. In other words, at least two through-holes that pass through the center in the short direction SR (corresponding to the predetermined direction) and are separated from each other should be formed in parts of the insulation layer 41 that does not overlap with the wiring patterns 43 arranged in the wiring area PA.

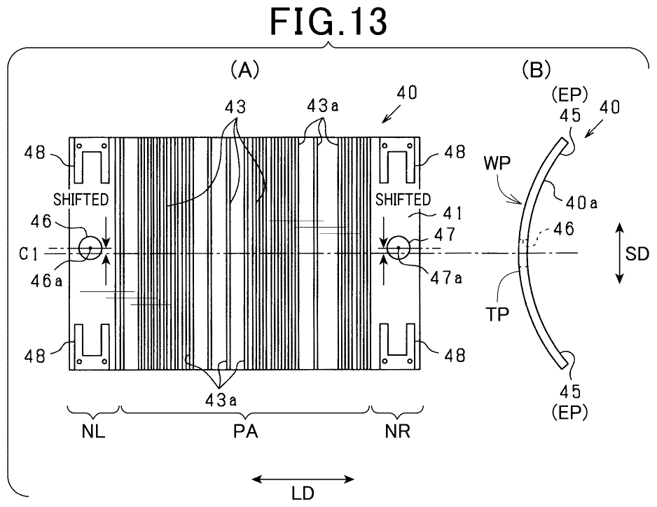

Another modification is provided in FIG. 13, which can also be in the foregoing embodiments and various modifications.

The center points 46a and 47a of the through-holes 46 and 47 may not always be located on the center line C1 vertically set in the short direction DT. For example, as shown in FIG. 13, such center points 46a and 47a may be biased in either way in the short direction DT. Even in this case, as long as the center line C1 passes the through-holes 46 and 47, a curve (which can also be referred to a warpage) can be formed when the through-holes 46 and 47 are formed reliably and controllably. Hence, when the FFC 40 is guided be shifted by the produced curve (warpage) in the short direction SR, the edges of the through-holes 46 and 47 may be positioned on the positioning pins 96 and 97 in a quick and smooth manner during the positioning process of the FFC 40. Thus, as described, when the edges of the through-holes 46 and 47 reach the tips of positioning pins 96 and 97, the positioning pin 96, 97 are easily and reliably inserted into the through-holes 46 and 47, respectively. In this way, the FFC 40 can be aligned with the positioning pins 96 and 97, and thus with the printed circuit boards 10 and 20.

Even in the case of the configuration shown in FIG. 13, the relative positional relationship provided between the printed circuit board 10 and 20 and the positioning pins 96 and 97 should be adjusted according to that provided between the through holes 46 and 47 in the insulation layer 41.

Therefore, in order to provide the insulation layer 41 with a properly curvature for a reliable and smooth positioning guidance thereof, it is sufficient that at least two through-holes are formed in the insulation layer 41, which intersect with the center line C1 in the short direction SR and are separated from each other.

In this way, the foregoing exemplified embodiments basically feature that, when the film-type circuit is loaded between two printed circuit boards for mutual electrical connection, the film-type circuit is given a curved shape in its length, i.e., a warpage in advance. How the warpage (or the curved surface in a side view) is generated positionally and in size can be controlled by adjustably adding through-holes to the film-type circuit. Hene, by using an inexpensive film-type circuit and positively utilizing the warpage (curve) generated on such an inexpensive film-type circuit, it is possible to improve yield and reduce costs during manufacturing.

Alternatively to the FFC employed in the foregoing embodiments modifications, a FPC (Flexible Printed Circuit) can be used as a film-type circuit instead of the FFC. In this case, an electric circuit (wiring patterns) should be formed by electrically conductive materials such as copper foil on a thin, soft, insulating base film made of insulating materials including polyimide. Even in this configuration, warpage may occur in the FPC due to the fact that there is an asymmetry in the components layered in the thickness direction of the FPC (film-type circuit).

In this modification, the base film (i.e., the insulation part) may cover both sides of an electrical circuit or only one side of the electrical circuit in order to expose the connection part of the electrical circuit.

The printed circuit boards 10 and 20 and film-type circuits (the foregoing FFC 40, an FPC, or other flexible connecting circuits) may be mounted on devices other than PLCs. In short, the film-type circuits of the foregoing embodiment and its modified examples can be applied to any film-type circuit that connects the wires of two printed circuit boards, regardless of the types of devices in which the circuits are mounted.

The plan-viewed shape of the FFC or FPC is not limited to a rectangle shape as described in the foregoing embodiment. In place of such rectangular FFC and FPC shown in for example FIG. 5, an FFC or FPC with a square shape or a subtrapezoidal shape with the foregoing curve (warpage) can be adopted to intervene between the two printed circuit boards and both ends in the short directions SD can be connected, respectively, to the electrodes of such printed circuits.

The foregoing embodiment and its modifications may be combined to the extent possible.

### Partial Reference Signs List

10 . . . printed circuit board,
13 . . . wiring,
20 . . . printed circuit board,
40 . . . . FFC (film-type circuit),
41 . . . insulation part,
43 . . . wiring (wiring part),
43a . . . connection part.
46 . . . through-hole,
47 . . . through-hole.

What is claimed is:

1. A film-type circuit to be connected with two printed circuit boards via the film-type circuit, comprising:
a wiring part formed of an electrically conductive material, formed to be a layer-shaped wiring patterns for conductive connection of the two printed circuit boards via the film-type circuit, and formed to have connection parts at both ends of the wiring part in a predetermined direction of the film-type circuit, and
an insulation layer formed of an electrically insulating material in a layered form and formed to cover the wiring part, the insulation layer being formed to expose a partial connection side of each of the connection parts, the connection side being connected to a corresponding one of the two printed circuit boards,
wherein the film-type circuit is curved in its length in the predetermined direction to produce warpage such that the partial connection side of each of the connection parts is directed inward in the curve and the connection parts positioned to be closer in the predetermined direction compared to a state where the film-type circuit is flat, and
the film-type circuit has at least two through-holes formed at designated positions in the film-type circuit, the designated positions being set to have no overlapping between the insulation layer and the wiring patterns, to be located in a center portion in the predetermined direction, and to be separated from each other in a direction orthogonal to the predetermined direction.

2. The film-type circuit according to claim 1, wherein the designated positions of the through-holes are at both end portions in a direction perpendicular to the predetermined direction.

3. The film-type circuit according to claim 2, wherein the respective through-holes have centers at the designated positions which are on a center line passing the center in the predetermined direction.

4. The film-type circuit according to claim 3, comprising a plurality of reinforcing terminals made of an electrically conductive material, each formed to have a width larger than a width of the respective wiring patterns, and positioned restrictively at end portions of the film-type circuit in both a direction orthogonal to the predetermined direction and the predetermined direction,
wherein the designated positions of the through-holes are set in end areas of the film-type circuit in the direction orthogonal to the predetermined direction, each of the designated positions in the respective end areas being located between two of the reinforcing terminals opposed to each other on the film-type circuit in the predetermined direction.

5. The film-type circuit according to claim 3, wherein the through-holes are different in sizes thereof from each other.

6. The film-type circuit according to claim 5, wherein the through-holes are two in number.

7. The film-type circuit according to claim 6, wherein the through-holes are equal in sizes thereof to each other.

8. The film-type circuit according to claim 5, wherein one of the designated positions at which the through-holes are formed is positioned between two of the wiring patterns.

9. The film-type circuit according to claim 8, wherein the through-holes are two in number and one of the designated positions is for one of the two through-holes,
the one of the two through-holes is smaller in diameter size than the other of the two through-holes, and
the one of the two through-holes is positioned between two of the wiring patterns.

10. The film-type circuit according to claim 1, wherein the film-type circuit is formed into a flat rectangular form in a plan view in a thickness direction thereof, the flat rectangular form providing the predetermined direction, and
the rectangular form having i) a wiring area provided with the wiring part composed of the wiring patterns is set in a direction orthogonal to the predetermined direction, and ii) two non-wiring areas with no wiring patterns are set on both end sides respectively in the direction orthogonal to the predetermined direction.

11. The film-type circuit according to claim 10, wherein the through-holes consists of two through-holes which are located in the two non-wiring areas respectively and are located on a virtual axis passing through a center in the predetermined direction.

12. The film-type circuit according to claim 11, wherein the two through-holes have diameters which are equal to each other or different from each other.

13. The film-type circuit according to claim 12, comprising four reinforcing terminals made of an electrically conductive material, wherein the four reinforcing terminals are positioned at four corners of the flat, sheet-shaped, and rectangular film-type circuit and the four corners are located in the non-wiring areas.

14. The film-type circuit according to claim 1, comprising a plurality of reinforcing terminals made of an electrically conductive material, each formed to have a width larger than a width of the respective wiring patterns, and positioned restrictively at end portions of the film-type circuit in both a direction orthogonal to the predetermined direction and the predetermined direction,
wherein the designated positions of the through-holes are set in end areas of the film-type circuit in the direction orthogonal to the predetermined direction, each of the designated positions in the respective end areas being located between two of the reinforcing terminals opposed to each other on the film-type circuit in the predetermined direction.

15. The film-type circuit according to claim 14, wherein the through-holes are two in number.

16. The film-type circuit according to claim 15, wherein the through-holes are equal in sizes thereof to each other.

17. A method of mutually connecting the two printed circuit boards via a film-type circuit, comprising steps of:
preparing a film-type circuit, comprising:
a wiring part formed of an electrically conductive material, formed to be a layer-shaped wiring patterns for conductive connection of the two printed circuit boards via the film-type circuit, and formed to have connection parts at both ends of the wiring part in a predetermined direction of the film-type circuit, and
an insulation layer formed of an electrical insulating material in a layered form and formed to cover the wiring part, the insulation layer still being formed to expose a partial connection side of each of the connection parts, the connection side being connected to a corresponding one of the two printed circuit boards,
wherein the film-type circuit is curved in its length in the predetermined direction to produce warpage such that the partial connection side of each of the connection parts is directed inward in the curve and the connection parts positioned to be closer in the predetermined direction compared to a state where the film-type circuit is flat, and
the film-type circuit has at least two through-holes formed at designated positions in the film-type circuit, the designated positions being set to have no overlapping between the insulation layer and the wiring patterns, to be located in a center portion in the predetermined direction, and to be separated from each other in a direction orthogonal to the predetermined direction;
fixing the two printed circuit boards onto a positioning jig provided with at least two positioning pins;
bringing the film-type circuit and the positioning pin close together such that the positioning pins are inserted into the through-holes, respectively, from the connection sides of the connection parts of the film-type circuit;
guiding the film-type circuit on and along the warpage such that the positioning pins are closer to the through-holes located at the center in the predetermined direction.

18. The method according to claim 17, wherein the positioning jig includes a first fixing member fixing one of the two printed circuit boards thereon and a second fixing member fixing the other of the two printed circuit boards, the positioning pins being arranged between the first and second fixing members in a direction orthogonal to the predetermined direction when the fixing step is completed,
wherein the fixing step is configured to connect the one of the printed circuit boards to the first fixing member and connect the other of the printed circuit boards to the second fixing member.

19. The method according to claim 17, wherein the film-type circuit comprises a plurality of reinforcing terminals made of an electrically conductive material, each formed to have a width larger than a width of the respective wiring patterns, and positioned restrictively at end portions of the film-type circuit in both a direction orthogonal to the predetermined direction and the predetermined direction,
each of the reinforcing terminals includes a first positing mark, and
each of the two printed circuit boards comprises connection terminals made an electrically conductive material and positioned thereon positionally corresponding to ones of the reinforcing terminals of the film-type circuit, and
each of the connection terminals include a second positioning mark,
the method comprising a step of aligning the first positioning marks with the second positioning marks when the positioning pins are inserted through the through-holes.

20. The method according to claim 19, wherein each of the printed circuit boards is provided with electrical wiring patterns which are positioned thereon corresponding to each of the connection parts of the film-type circuit, the method comprising:
applying a heating tool to both the connection parts of the film-type circuit and the reinforcing terminals to be heated and pressed to the wiring patterns of the printed circuit boards, whereby, every printed circuit board, the wiring patterns of the printed circuit board and the connection side of the connection part of the film-type circuit are connected to each other, and also the connection terminals of the printed circuit board and the reinforcing terminals of the film-type circuit are connected to each other.
